(19) United States
(12) Patent Application Publication
(10) Pub. No.: US 2025/0379163 A1
(43) Pub. Date: Dec. 11, 2025

(54) MICROELECTRONIC ASSEMBLIES HAVING A GLASS LAYER SUBSTRATE WITH INTEGRATED CAPACITORS

(71) Applicant: Intel Corporation, Santa Clara, CA (US)

(72) Inventors: Mahdi Mohammadighaleni, Phoenix, AZ (US); Wendy Lin, Chandler, AZ (US); Dilan Seneviratne, Phoenix, AZ (US); Thomas S. Heaton, Mesa, AZ (US); Nevin Erturk, Atlanta, GA (US); Joshua Stacey, Chandler, AZ (US); Jieying Kong, Chandler, AZ (US); Srinivas Venkata Ramanuja Pietambaram, Chandler, AZ (US); Mohammad Mamunur Rahman, Gilbert, AZ (US)

(73) Assignee: Intel Corporation, Santa Clara, CA (US)

(21) Appl. No.: 18/735,670

(22) Filed: Jun. 6, 2024

(51) Int. Cl. H01L 23/64; H01L 21/48; H01L 23/498

(52) U.S. Cl. CPC H01L 23/642; H01L 21/4857; H01L 23/49822; H01L 23/49838

(57) ABSTRACT

Microelectronic assemblies, related devices and methods, are disclosed herein. In some embodiments, an integrated circuit (IC) substrate may include a glass layer having a surface; and a vertical capacitor, the vertical capacitor including a vertical structure extending partially through the glass layer from the surface of the glass layer; a metal-insulator-metal (MIM) stack having a top electrode, an insulator layer, and a bottom electrode, the MIM stack on the surface of the glass layer and extending at least partially into the vertical structure; and a conductive liner layer between the bottom electrode and the glass layer, and electrically coupled to the bottom electrode.

### BACKGROUND

Integrated circuit (IC) packages may include capacitors for managing power delivery to IC dies. Typically, IC packages may include capacitors surface-mounted on a backside of a die or on a land side of a circuit board.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1A is a side, cross-sectional view of an example microelectronic assembly including a capacitor according to some embodiments of the present disclosure.

FIG. 1B is a magnified portion of the capacitor of FIG. 1A according to some embodiments of the present disclosure.

FIG. 1C is a magnified portion of another example capacitor according to some embodiments of the present disclosure.

FIGS. 2A and 2B are simplified, schematic top views of example capacitors according to some embodiments of the present disclosure.

FIGS. 3A-3D are simplified side, cross-sectional views of other example capacitors according to some embodiments of the present disclosure.

FIGS. 4A-41 are side, cross-sectional views of various stages in an example process for manufacturing a microelectronic assembly including an example capacitor according to some embodiments of the present disclosure.

FIGS. 5A-5C are side, cross-sectional views of various stages in an example process for manufacturing a microelectronic assembly including another example capacitor according to some embodiments of the present disclosure.

FIG. 6 is a cross-sectional side view of an IC device assembly that may include a microelectronic assembly, in accordance with any of the embodiments disclosed herein.

FIG. 7 is a block diagram of an example electrical device that may include a microelectronic assembly, in accordance with any of the embodiments disclosed herein.

### DETAILED DESCRIPTION

Communicating large numbers of signals between two or more dies in a multi-die IC package is challenging due to the increasingly small size of such dies, thermal constraints, and power delivery constraints, among others. Typically, IC packages include prefabricated capacitors that may be surface-mounted on a die or a circuit board. For example, IC packages may include die side capacitors (DSC) mounted on a backside of a die or land side capacitors (LSC) mounted on a circuit board. Surface-mounted capacitors are likely to increase latency of power delivery due to increased power trace distance, occupy limited surface area on the die and/or circuit board, and increase overall z-height (e.g., thickness) of the IC package. One conventional solution for incorporating capacitors is to build capacitors in the top dies as part of the voltage regulator circuitry necessary for the power delivery function of the IC package, but many dies cannot incorporate a sufficient number of capacitors to meet capacitance demands of the power delivery network. Another conventional solution is to incorporate capacitors in a package substrate, such as trench capacitors. A “trench capacitor,” also known as a “via capacitor” and collectively referred to herein as a “vertical capacitor” (VC), is constructed by creating a trench or via opening in a substrate and forming a metal-insulator-metal (MIM) stack in the opening. The MIM stack of the VC typically uses a thin refractive metal (e.g., titanium nitride (TiN)), as the metal electrodes. Such thin refractive metals have high resistivity and cause high equivalent series resistance (ESR) of the capacitors. Various ones of the embodiments disclosed herein may help achieve higher capacitance at higher frequencies and improved power efficiency of VCs in a glass layer of a package substrate. Further, the microelectronic assemblies disclosed herein may exhibit better power delivery relative to conventional approaches by coupling one or both of the thin refractive metal layers of the MIM stack to a highly conductive liner material and directly coupling to a ground source (e.g., VSS) or, if both, to a ground source (e.g., VSS) and a positive supply source (e.g., VDD), such that “fresh electricity” may be delivered to the capacitor. Various ones of the embodiments disclosed herein may further help achieve improved power efficiency with greater design flexibility, relative to conventional approaches, as having VCs with low ESR reduces the number of contacts required to the VCs. The microelectronic assemblies disclosed herein may be particularly advantageous for power hungry applications (e.g., servers and high end laptops) where glass substrates may reduce warpage and enable large Form Factor Devices.

Microelectronic assemblies, related devices and methods, are disclosed herein. In some embodiments, an integrated circuit (IC) substrate may include a glass layer having a surface; and a vertical capacitor, the vertical capacitor including a vertical structure extending partially through the glass layer from the surface of the glass layer; a metal-insulator-metal (MIM) stack having a top electrode, an insulator layer, and a bottom electrode, the MIM stack on the surface of the glass layer and extending at least partially into the vertical structure; and a conductive liner layer between the bottom electrode and the glass layer, and electrically coupled to the bottom electrode.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” (IC) means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die,” “IC,” and “IC die.” Note that the terms “microelectronic component,” “chip,” “chiplet,” “die,” “IC,” and “IC die,” and similar variations may be used interchangeably herein. The terms “interconnect component,” “bridge die,” “interconnect bridge,” and “interconnect die,” and similar variations may be used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. A dielectric material may include any suitable dielectric material commonly used in semiconductor manufacture, such as silicon and one or more of oxygen, nitrogen, hydrogen, and carbon (e.g., in the form of silicon oxide, silicon nitride, silicon oxynitride, or silicon carbon nitride); a polyimide material; or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In silicon-on-insulator, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a PIC, “interconnect” may also describe any element formed of a material that is optically conductive for providing optical connectivity to one or more elements associated with the PIC. In such cases, the term “interconnect” may refer to optical waveguides, including optical fiber, optical splitters, optical combiners, optical couplers, and optical vias.

As used herein, the term “optical element” includes arrangements of forms fabricated in ICs to receive, transform and/or transmit optical signals as described herein. It may include optical conductors such as waveguides, grating coupler, electromagnetic radiation sources such as lasers, and electro-optical devices such as photodetectors.

The term “waveguide” refers to any structure that acts to confine and guide the propagation of light from one location to another location typically through a substrate material such as silicon or glass. In various examples, waveguides can be formed from silicon, doped silicon, silicon nitride, glasses such as silica (e.g., silicon dioxide or SiO2), borosilicate (e.g., 70-80 wt % SiO2, 7-13 wt % of B2O3, 4-8 wt % Na2O or K2O, and 2-8 wt % of Al2O3) and so forth. Waveguides may be formed using various techniques including but not limited to forming waveguides in situ. For example, in some embodiments, waveguides may be formed in situ in glass using low temperature glass-to-glass bonding or by laser direct writing (e.g., a laser written waveguide). Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive vertical element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example,” an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

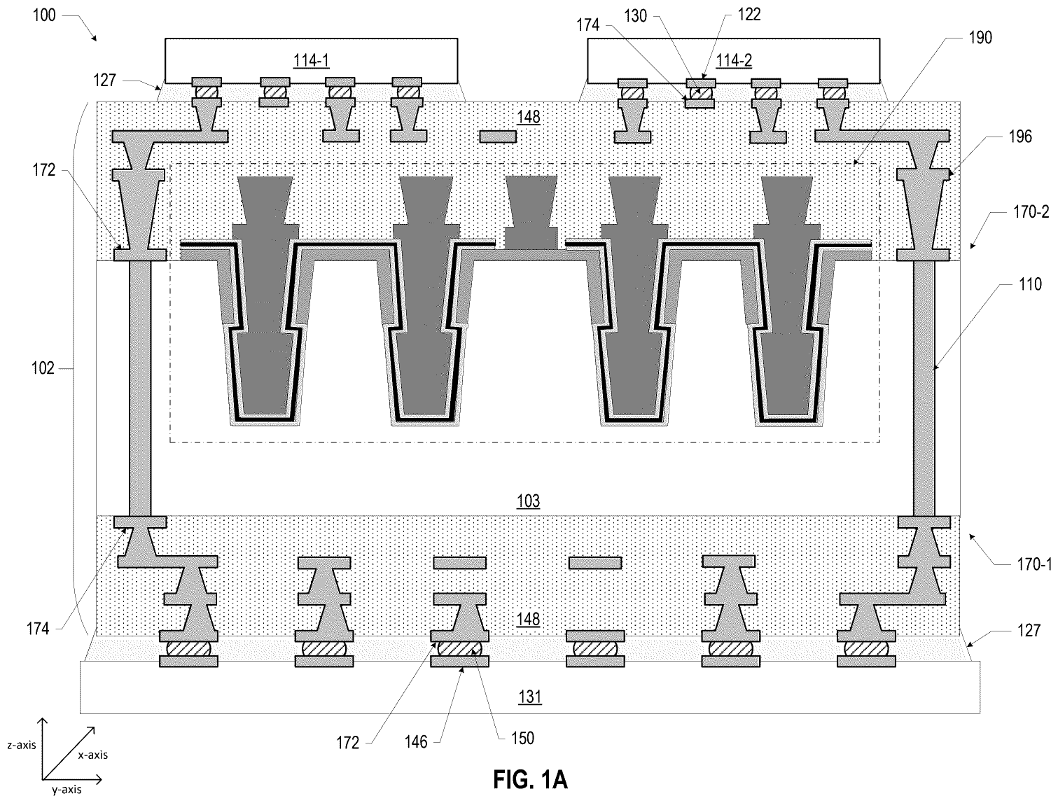

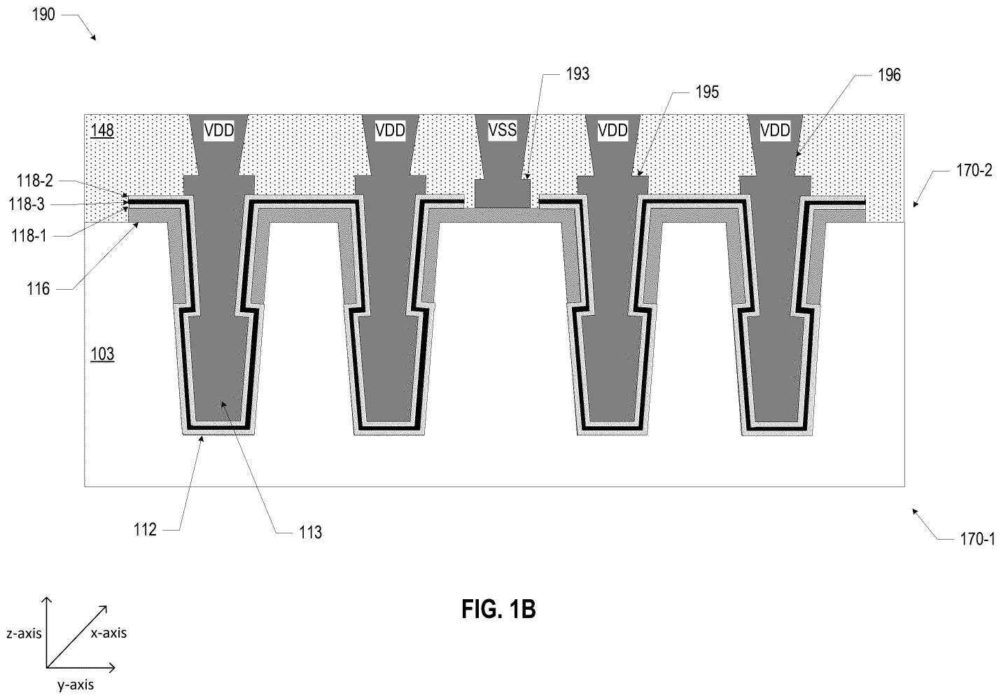

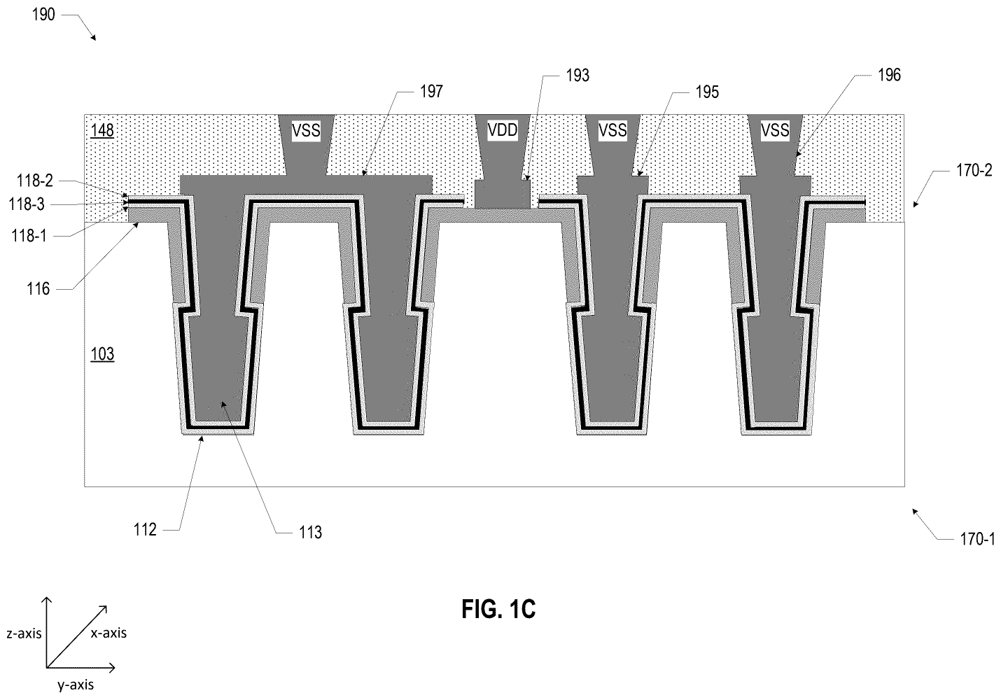

For convenience, if a collection of drawings designated with different letters are present (e.g., FIGS. 1A and 1B), such a collection may be referred to herein without the letters (e.g., as “FIG. 1”). Similarly, if a collection of reference numerals designated with different numerals and/or letters are present (e.g., 114-1, 114-2, etc.), such a collection may be referred to herein without the numerals (e.g., as “114”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

FIG. 1A is a side, cross-sectional view of a microelectronic assembly 100 according to some embodiments of the present disclosure. The microelectronic assembly 100 may include a package substrate 102 having a glass layer 103, also referred to herein as a “core” or a “glass core,” and a VC 190. FIG. 1B is a magnified portion of the VC 190 of FIG. 1A. As shown in FIG. 1B, the VC 190 may include a glass layer 103 having a first surface 170-1 (e.g., a bottom surface) and an opposing second surface 170-2 (e.g., a top surface), vertical structures 112 (e.g., blind vias or trenches) extending partially through the glass layer 103 from the second surface 170-2 including a conductive material 113 filling the vertical structures 112, a conductive liner 116 on the second surface 170-2 of the glass layer and extending at least partially in the vertical structures 112, and a MIM stack 118 conformally on the conductive liner 116 and in the vertical structure 112. The MIM stack 118 includes a first metal layer 118-1 (e.g., a bottom electrode), a second metal layer 118-2 (e.g., a top electrode), and an insulting layer 118-3 in between the first and second metal layers 118-1, 118-2. The conductive liner 116 is electrically coupled to the first metal layer 118-1 of the MIM stack 118 and to a conductive pad 193. A first capacitor plate (e.g., a bottom electrode) may be formed by coupling the conductive pad 193 to a ground source (e.g., VSS). The second metal layer 118-2 of the MIM stack 118 is electrically coupled to a conductive material 113 of the vertical structure 112 and to a conductive pad 195. A second capacitor plate (e.g., a top electrode) may be formed by coupling the conductive pad 195 to a positive supply voltage (e.g., VDD). In some embodiments, the source connections may inverted, such that the conductive pad 193 of the bottom electrode is coupled to VDD and the conductive pad 195 of the top electrode is coupled to VSS (e.g., as shown in FIG. 1C). The VC 190 may enable improved power delivery to components of the microelectronic assembly 100, including die 114.

Although FIG. 1B shows each individual vertical structure 112 electrically coupled to a single VDD source, multiple vertical structures 112, including two or more vertical structures 112, may be electrically coupled to a single VDD source. For example, as shown in FIG. 1C, two vertical structures 112 may be coupled by conductive pad 197 to a single VDD source.

The conductive liner 116 may include any suitable highly conductivity (e.g., low resistivity) metal, for example, one or more of copper, silver, gold, aluminum, ruthenium, and tungsten. The conductive liner 116 may be formed using any suitable process, such as physical vapor deposition (PVD) or atomic layer deposition (ALD). The conductive liner 116 may have any suitable dimensions. In some embodiments, the conductive liner 116 has a thickness (e.g., z-dimension on the second surface 170-2 of the glass layer 103 and y-dimension on the side surface of the vertical structure 112) between 20 nanometers and 200 nanometers. A thickness of the conductive liner 116 on the second surface 170-2 of the glass layer 103 may be a same thickness or may be a different thickness than on the side surface of the vertical structure 112.

The metal layers 118-1, 118-2 of the MIM stack 118 may be formed using any suitable process, such as ALD, and may include any suitable material, such as titanium, nitrogen, and ruthenium (e.g., in the form of titanium nitride and ruthenium), and may have any suitable dimensions, for example, an individual metal layer 118-1, 118-2 may have a thickness between 2 nanometers and 50 nanometers. The insulating layer 118-3 of the MIM stack 118 may be formed using any suitable process, such as ALD, and may include any suitable material, such as silicon oxide, and may have suitable dimensions, for example, the insulating layer 118-3 may have a thickness between 2 nanometers and 50 nanometers.

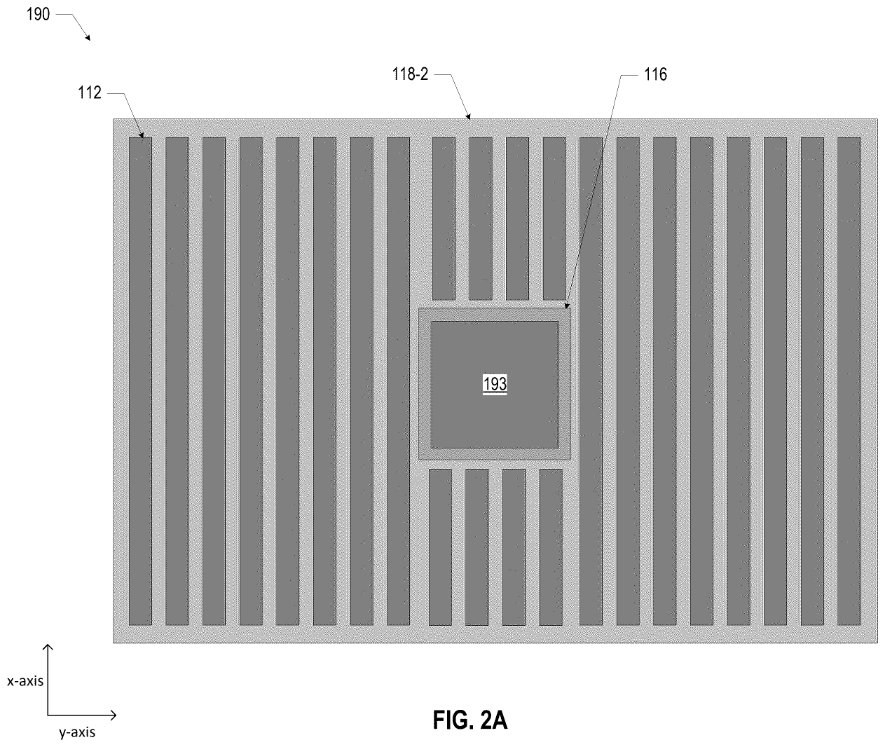

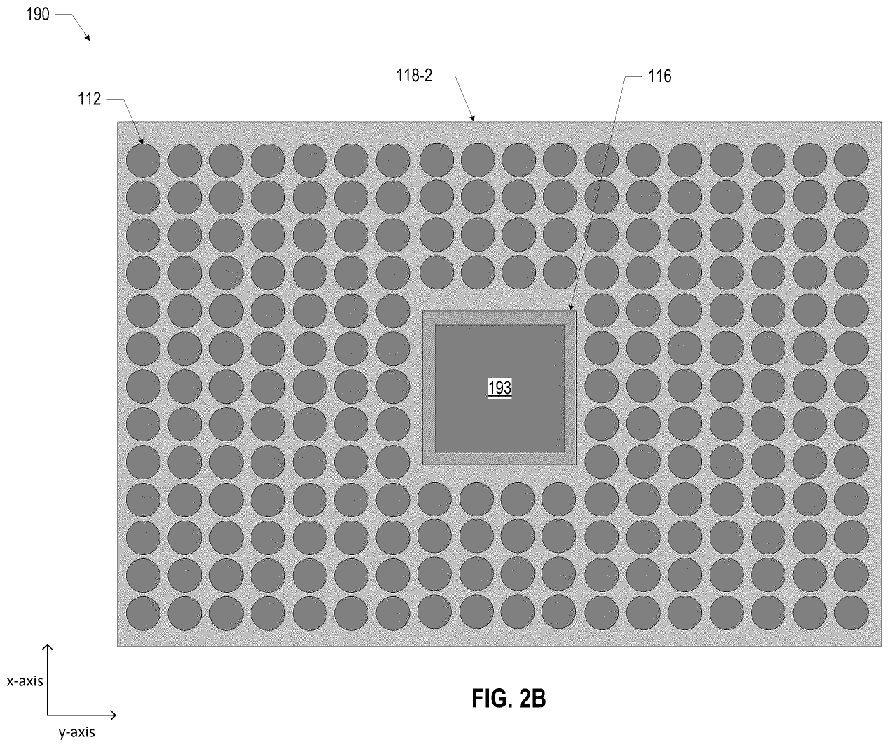

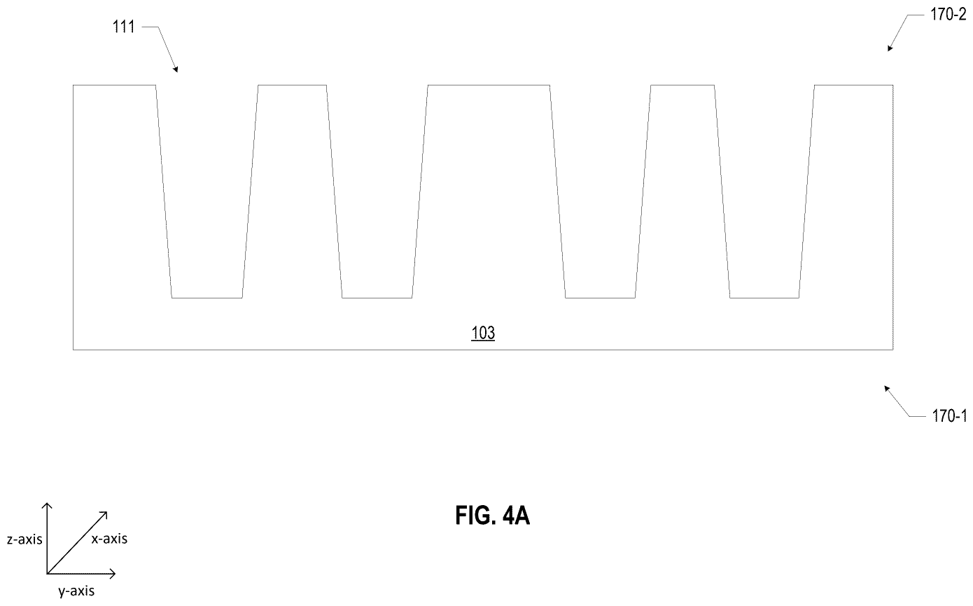

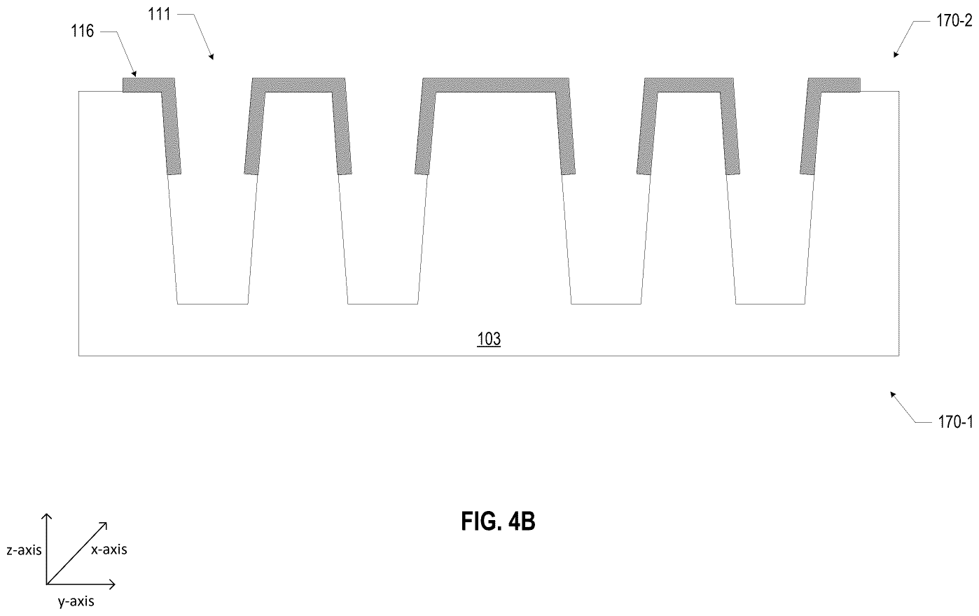

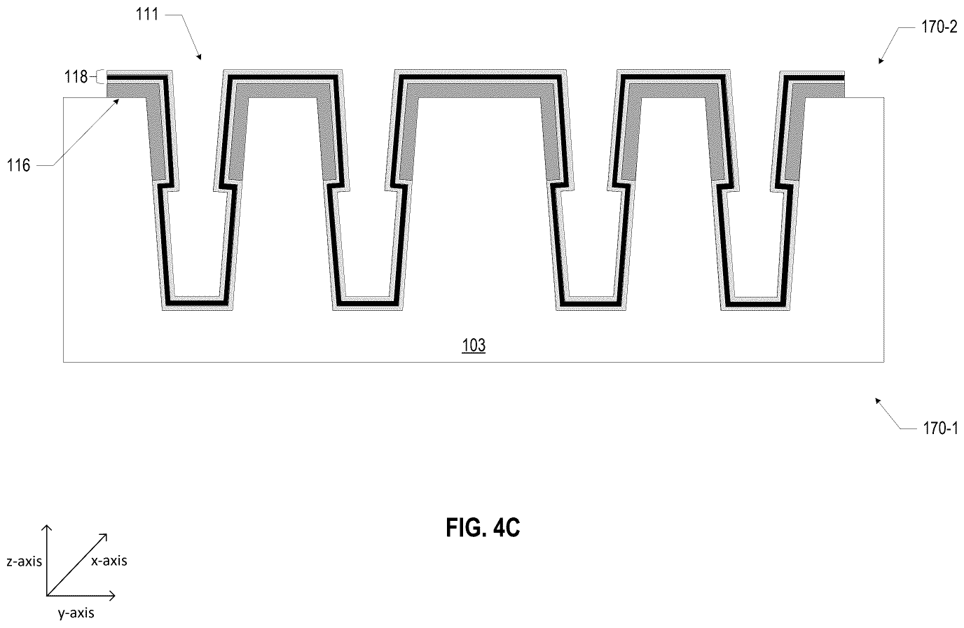

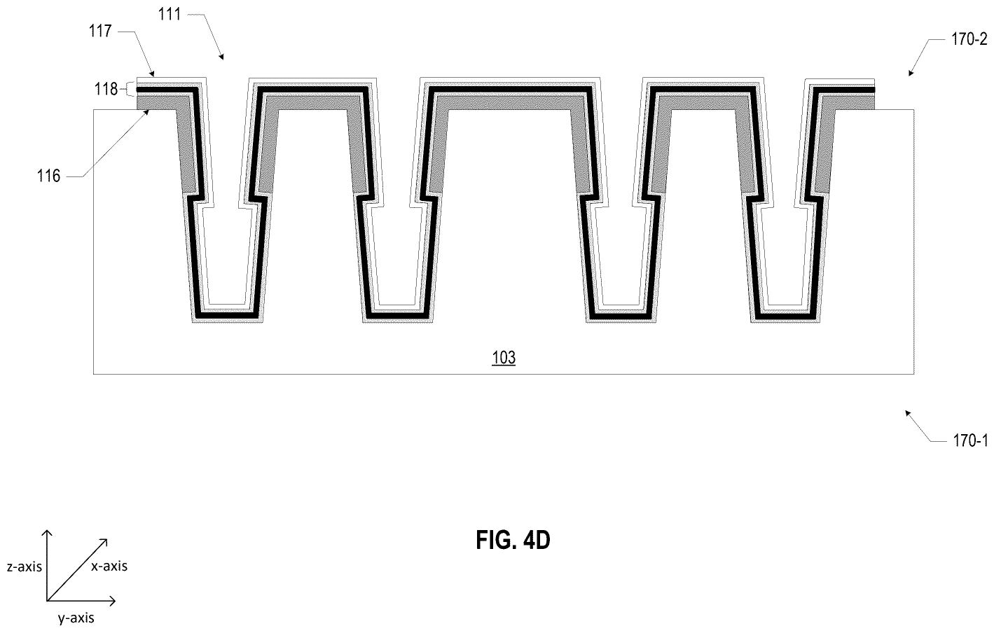

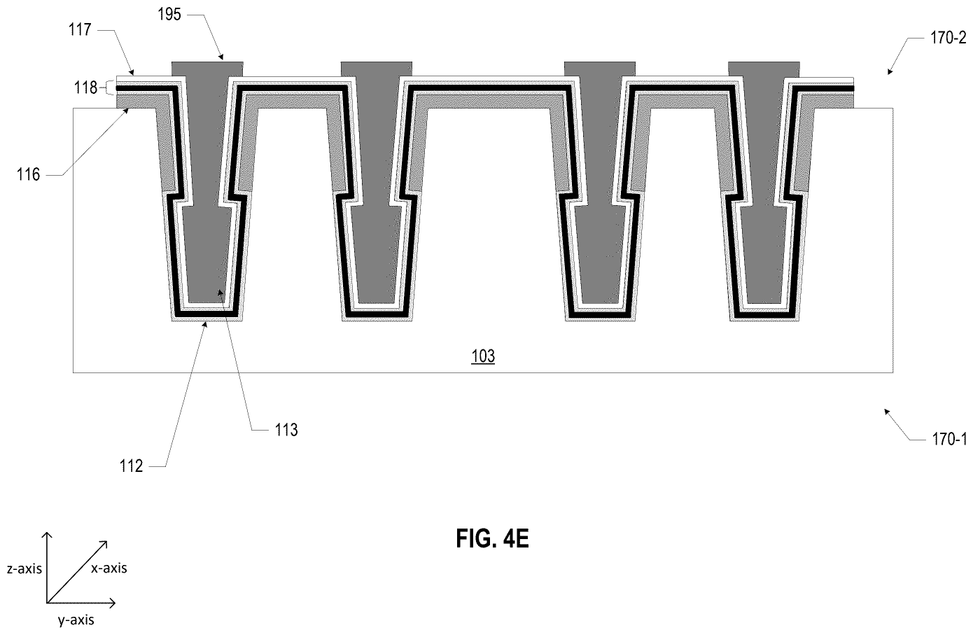

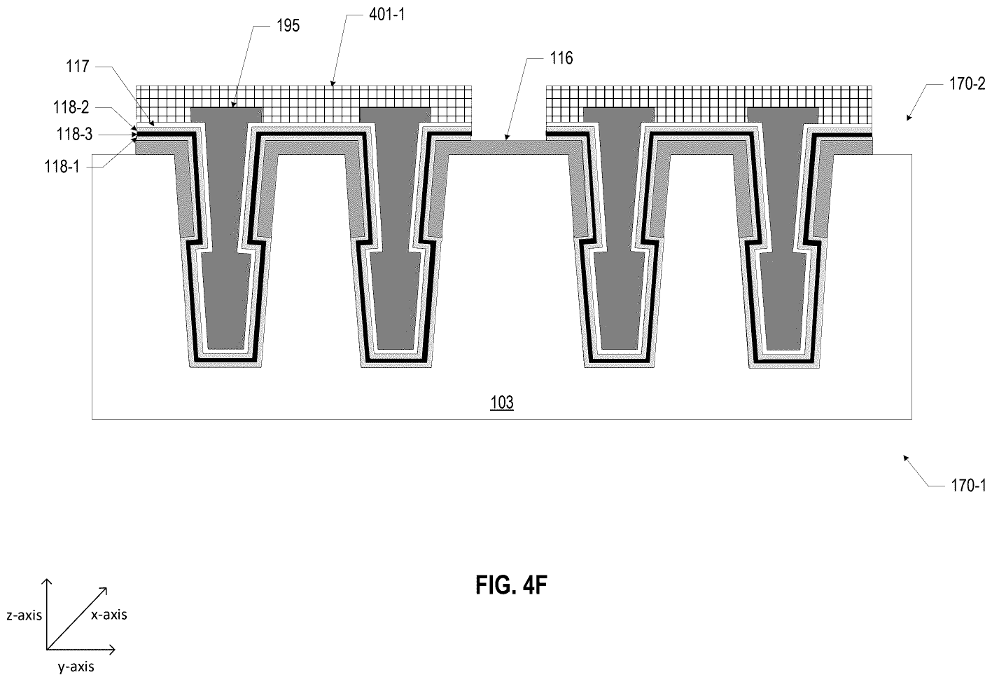

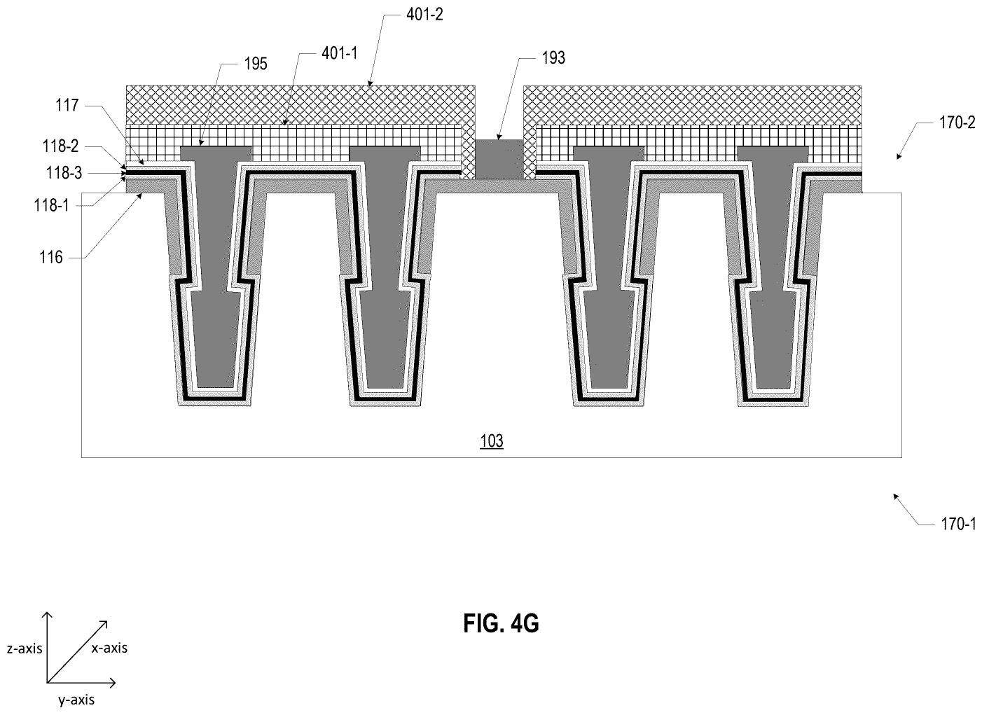

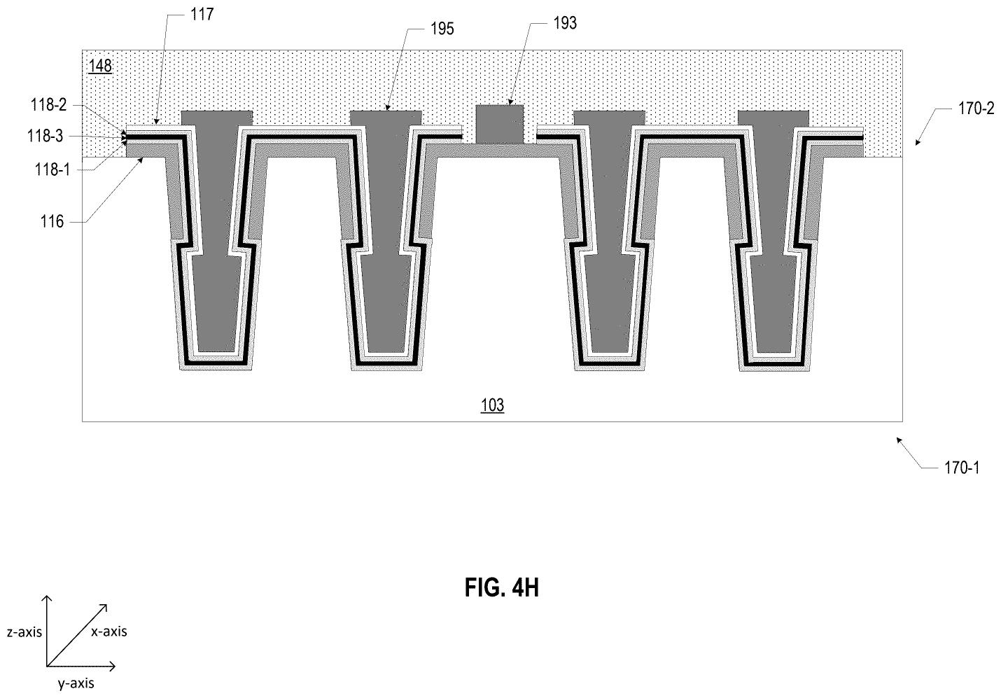

The vertical structures 112 may have any suitable dimensions and shape. In some embodiments, the vertical structures 112 may have a depth (e.g., z-height) between 200 microns and 300 microns. In some embodiments, the vertical structures 112 include trenches (e.g., as shown in FIG. 2A). In some embodiments, a trench may have a width (e.g., y-dimension) between 10 microns and 20 microns and a length (e.g., x-dimension) between 30 microns and 500 microns. In some embodiments, the vertical structures 112 include vias (e.g., as shown in FIG. 2B). In some embodiments, a via may have a diameter (e.g., xy-dimension) between 10 microns and 20 microns. The vertical structures 112 may include any suitable conductive material 113, such as copper, aluminum, or tin. The vertical structures 112 may be formed using any suitable process, for example, laser drilling openings in the second surface 170-2 of the glass layer 103, then depositing the conductive liner 116, depositing the MIM stack 118, and depositing a conductive material 113 in the openings, as described below with reference to FIG. 4.

A material of the glass layer 103 may include glass, such as bulk transparent glass, and also may include any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the glass layer 103 may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, the glass layer 103 may be an amorphous solid glass layer. In some embodiments, the glass layer 103 may include silicon and oxygen, as well as any one or more of aluminum, boron, magnesium, calcium, barium, tin, sodium, potassium, strontium, phosphorus, zirconium, lithium, titanium, and zinc. In some embodiments, the glass layer 103 may include a material, e.g., any of the materials described above, with a weight percentage of silicon being at least about 0.5%, e.g., between about 0.5% and 50%, between about 1% and 48%, or at least about 23%. For example, if the glass layer 103 is fused silica, the weight percentage of silicon may be about 47%. In some embodiments, the glass layer 103 may include at least 23% silicon and/or at least 26% oxygen by weight, and, in some further embodiments, the glass layer 103 may further include at least 5% aluminum by weight. In some embodiments, the glass layer 103 may include any of the materials described above and may further include one or more additives such as Al₂O₃, B₂O₃, MgO, CaO, SrO, BaO, SnO₂, Na₂O, K₂O, SrO, P₂O₃, ZrO₂, Li₂O, Ti, and Zn. In some embodiments, the glass layer 103 may be a layer of glass that does not include an organic adhesive or an organic material. The glass layer 103 may be distinguished from, for example, the “prepreg” or “RF4” core of a PCB substrate which typically includes glass fibers embedded in a resinous organic material such as an epoxy. In some embodiments, a cross-section of the glass layer 103 in an x-z plane, a y-z plane, and/or an x-y plane of an example coordinate system, shown in FIG. 1A, may be substantially rectangular. In some embodiments, a thickness of a glass layer 103 may be between 50 microns and 2 millimeters (i.e., between 100 microns and 1 millimeter).

Returning to FIG. 1A, the package substrate 102 of the microelectronic assembly 100 may further include through-glass vias (TGVs) 110 through the glass layer 103, and a dielectric material 148 with conductive pathways 196 at the first and second surfaces 170-1, 170-2 of the glass layer 103. TGVs 110 may have any suitable size and shape. A diameter (e.g., xy-dimension) of the individual TGVs 110 may be between 5 microns and 100 microns (e.g., between 20 microns and 50 microns). TGVs 110 are shown in FIG. 1A as having straight, parallel sides; however, in various embodiments, the sides may be tapered, tapered towards a center (e.g., have an hourglass shape), and/or have other irregularities depending on the processing conditions for generating TGVs 110. TGVs 110 may be formed using any suitable process, including, for example, laser drilling via openings through the glass layer 103 and depositing a conductive material in the openings. TGVs 110 may be formed of any suitable conductive material, such as copper, silver, nickel, gold, aluminum, or other metals or alloys. In some embodiments, a pitch of the TGVs 110 may be between 25 microns and 200 microns (e.g., between 75 microns and 150 microns).

The dielectric material 148 may include a set of first conductive contacts 172 at the bottom surface and a set of second conductive contacts 174 at the top surface, where the conductive pathways 196 electrically couple individual ones of the first and second conductive contacts 172, 174. The dielectric material 148 and conductive pathways 196 may be manufactured using any suitable technique, such as a semi-additive process, a subtractive etching technique, or other conventional substrate package techniques. In some embodiments, the dielectric material 148 and conductive pathways 196 may be formed as part of a redistribution layer (RDL) process. In some embodiments, a dielectric material 148 may include bismaleimide triazine (BT) resin, polyimide materials, epoxy materials (e.g., glass reinforced epoxy matrix materials, epoxy build-up films, or the like), mold materials, oxide-based materials (e.g., silicon dioxide or spin on oxide), or low-k and ultra low-k dielectric (e.g., carbon-doped dielectrics, fluorine-doped dielectrics, porous dielectrics, and organic polymeric dielectrics). The TGVs 110 in the glass layer 103 may electrically couple the conductive pathways 196 in the dielectric materials 148 on the first and second surfaces 170-1, 170-2 of the glass layer 103. TGVs 110 in glass layer 103 may enable power, ground and signal connectivity to components located on either side of the glass layer 103, for example, between dies 114-1, 114-2 and a circuit board 131.

The microelectronic assembly 100 may further include die 114-1 and die 114-2 electrically coupled to conductive pathways 196 in the dielectric material 148 at the second surface 170-2 of the glass layer 103 by interconnects 130. In particular, conductive contacts 122 on a bottom surface of die 114-1, 114-2 may be electrically and mechanically coupled to conductive contacts 174 at a top surface of the dielectric material 148 by interconnects 130.

Interconnects 130 may enable electrical coupling between die 114-1 and die 114-2 through conductive pathways 196 in the dielectric material 148. Interconnects 130 disclosed herein may take any suitable form. In some embodiments, a set of interconnects 130 may include solder (e.g., solder bumps or balls that are subject to a thermal reflow to form the interconnects 130). Interconnects 130 that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of interconnects 130 may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression. In some embodiments, interconnects 130 disclosed herein may have a pitch between about 18 microns and 75 microns. Although FIG. 1A shows dies 114-1, 114-2 electrically coupled by interconnects 130, dies 114-1, 114-2 may be electrically coupled by any suitable interconnects, including hybrid bonding and may have a pitch between 2 microns and 70 microns.

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked). In various embodiments, die 114 may include, or be a part of, one or more of a central processing unit (CPU), a memory device (e.g., a high-bandwidth memory device), a logic circuit, input/output circuitry, a transceiver such as a field programmable gate array transceiver, a gate array logic such as a field programmable gate array logic, of a power delivery circuitry, a III-V or a III-N device such as a III-N or III-N amplifier (e.g., GaN amplifier), Peripheral Component Interconnect Express (PCIe) circuitry, Double Data Rate (DDR) transfer circuitry, or other electronic components known in the art. In some embodiments, die 114-1 and die 114-2 may include different functionalities. As used herein, the term “functionality” with reference to a die refers to one or more functions (e.g., capability, task, operation, action, instruction execution, etc.) that the die in question can perform. For example, die 114-1 may be a CPU and die 114-2 may be a Graphics Processing Unit (GPU) or memory. In other embodiments, die 114-1 and die 114-2 may include the same or similar functionalities. For example, die 114-1 and die 114-2 may each include memory.

The microelectronic assembly 100 of FIG. 1A may also include an underfill material 127. In some embodiments, the underfill material 127 may extend around the associated interconnects 130 between die 114-1, 114-2 and the dielectric material 148. The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering die 114-1, 114-2 to the dielectric material 148 when forming the interconnects 130, and then polymerizes and encapsulates the interconnects 130. The underfill process may include dispensing underfill material in liquid form, allowing the material to flow and fill the interstitial gaps around interconnects 130, and subjecting the assembly to a curing process, such as baking, to solidify the material. In some embodiments, an underfill material 127 may be omitted. Although FIG. 1A shows two separate underfill 127 portions under die 114-1 and die 114-2, the underfill 127 may be a single underfill 127 under die 114-1 and die 114-2. The underfill material 127 may be selected to have a coefficient of thermal expansion (CTE) that may mitigate or minimize the stress between die 114 and the dielectric material 148 arising from uneven thermal expansion in the microelectronic assembly 100. In some embodiments, the CTE of the underfill material 127 may have a value that is intermediate to the CTE of the dielectric material 148 and a CTE of the insulating material of die 114.

The microelectronic assembly 100 of FIG. 1A may also include a circuit board 131. In particular, conductive contacts 172 on a bottom surface of the dielectric material 148 at the first surface 170-1 of the glass layer 103 may be electrically coupled to conductive contacts 146 on a top surface of the circuit board 131 by interconnects 150. Interconnects 150 disclosed herein may take any suitable form, including solder balls for a ball grid array arrangement, pins in a pin grid array arrangement or lands in a land grid array arrangement, or any of the forms described above with reference to interconnects 130. As shown in FIG. 1A, in some embodiments, a set of interconnects 150 may include solder (e.g., solder bumps or balls that are subject to a thermal reflow to form the interconnects 150). In some embodiments, the interconnects 150 disclosed herein may have a pitch between about 50 microns and 300 microns. In some embodiments, an underfill material 127 may extend around the associated interconnects 150 between the dielectric material 148 and the circuit board 131. The circuit board 131 may be a motherboard, for example, and may have other components attached to it. The circuit board may include conductive pathways and other conductive contacts for routing power, ground, and signals through the circuit board, as known in the art. In some embodiments, the interconnects 150 may not couple to a circuit board 131, but may instead couple to another IC package, an interposer, or any other suitable component.

Although FIG. 1 shows a particular number and arrangement of components (e.g., a single VC 190, including a particular number and arrangement of vertical structures 112, conductive liners 116, and conductive pads 193, 195), a microelectronic assembly 100 may have any suitable number and arrangement of components, including more than one VC 190 and a different number and arrangement of vertical structures 112, conductive liners 116, and conductive pads 193, 195.

FIG. 2A is a simplified, schematic top view of an example VC 190 according to some embodiments of the present disclosure. FIG. 2A shows the vertical structures 112, as trenches, arranged around a conductive pad 193. The conductive liner 116 (e.g., as shown in FIG. 1B) is electrically coupled to the conductive pad 193, and the second metal layer 118-2 of the MIM stack 118 (e.g., as shown in FIG. 1B) is electrically coupled to the conductive material 113 in the vertical structures 112 (e.g., as shown in FIG. 1B).

FIG. 2B shows a simplified schematic top view of another example VC 190 according to some embodiments of the present disclosure. The configuration of the embodiment shown in the figure is like that of FIG. 2A, except for differences as described further. The configuration of FIG. 2B shows the vertical structures 112, as vias, arranged around a conductive pad 193. The conductive liner 116 (e.g., as shown in FIG. 1B) is electrically coupled to the conductive pad 193, and the second metal layer 118-2 of the MIM stack 118 (e.g., as shown in FIG. 1B) is electrically coupled to the conductive material 113 in the vertical structures 112 (e.g., as shown in FIG. 1B). Although FIG. 2B illustrates the vias having a circular cross-sectional shape, the vias may have any suitable cross-sectional shape, including rectangular, triangular, or oval, for example. Although FIGS. 2A and 2B illustrate a particular number and arrangement of vertical structures 112 and conductive pads 193, a VC 190 may have any suitable number and arrangement of vertical structures 112 and conductive pads 193. As shown in FIGS. 2A and 2B, the plurality of vertical structures 112 may have a common top electrode and a common bottom electrode (e.g., the MIM stack 118 covers the second surface 170-2 of the glass layer 103 and extends at least partially into each of the plurality of vertical structures 112, for example, as shown in FIG. 1, so that the top electrodes of the plurality of the vertical structures are electrically coupled to form a common top electrode and the bottom electrodes of the plurality of the vertical structures are electrically coupled to form a common bottom electrode). The conductive liner 116 may cover the second surface 170-2 of the glass layer 103 and extend at least partially into each of the plurality of vertical structures 112, for example, as shown in FIG. 1.

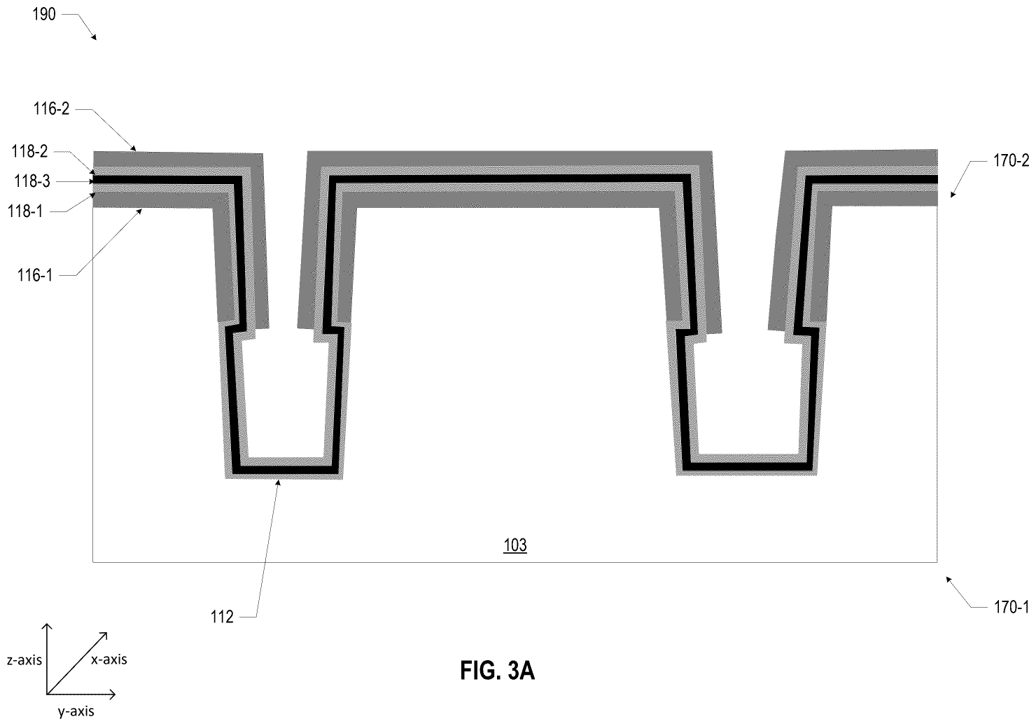

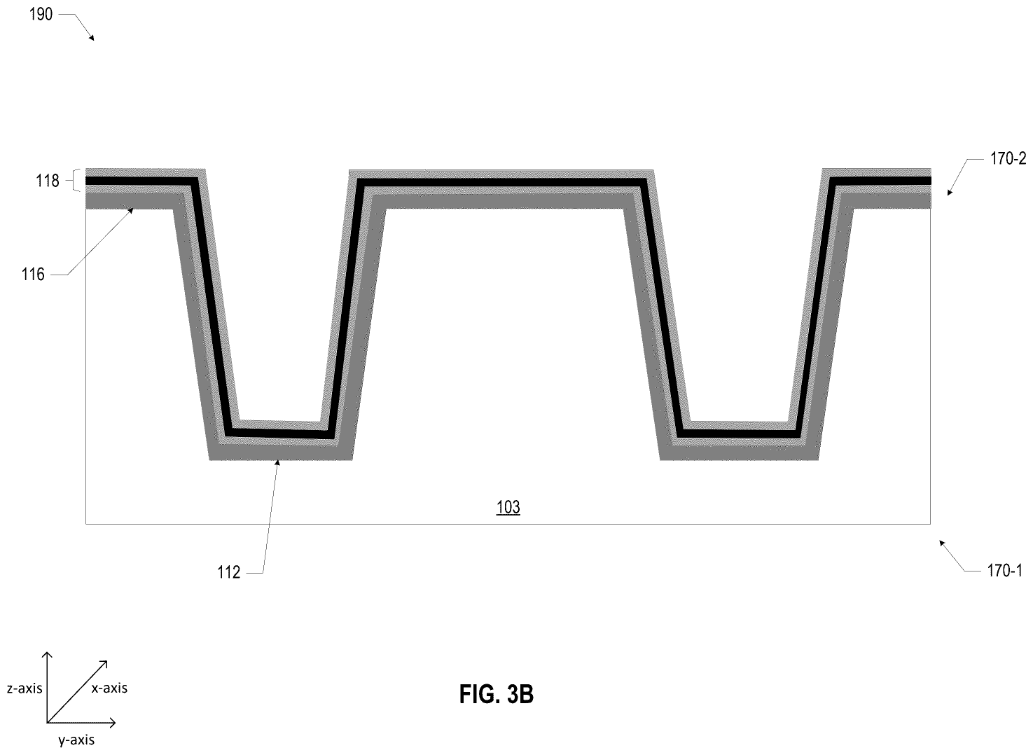

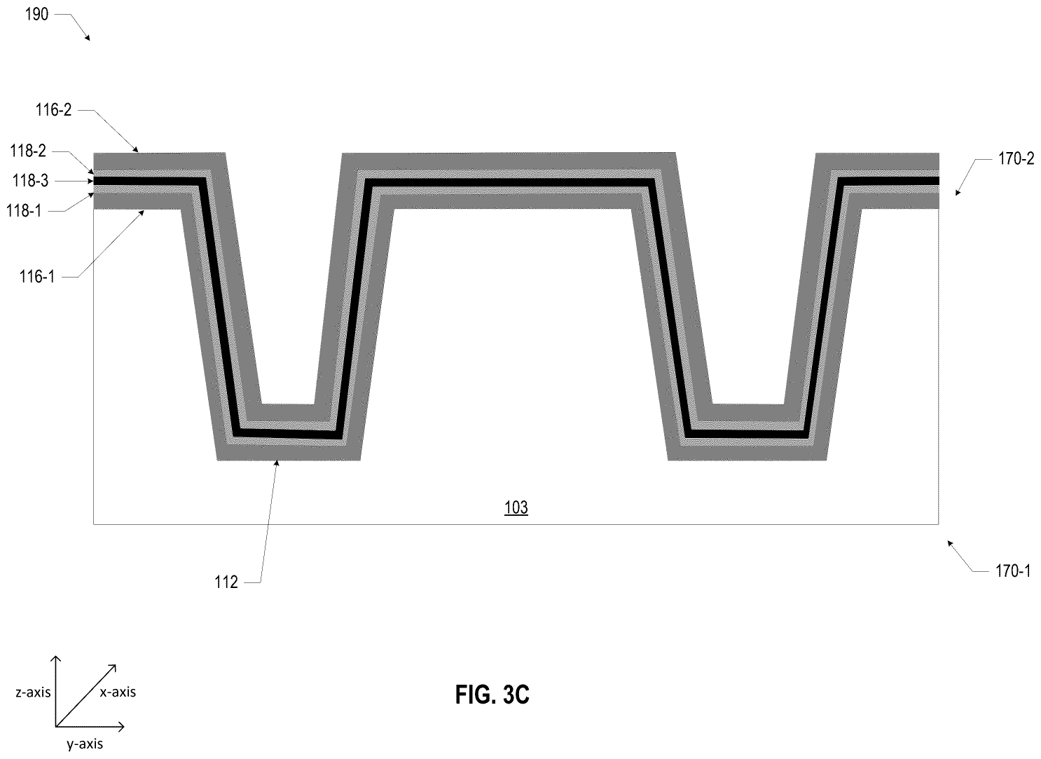

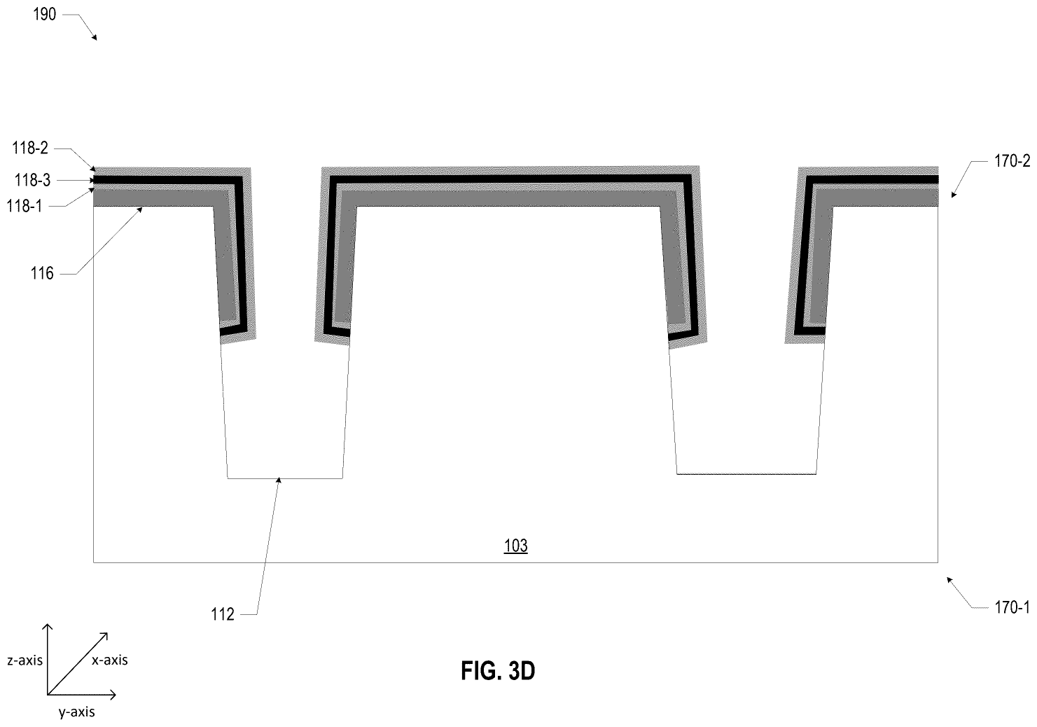

FIGS. 3A-3D are simplified side, cross-sectional views of other example VCs 190 according to some embodiments of the present disclosure. The configuration of the embodiment shown in FIG. 3A is like that of FIG. 1B, except for differences as described further. The configuration of the VC 190 in FIG. 3A includes a first conductive liner 116-1 (e.g., the conductive liner 116, as shown in FIG. 1B) and further includes a second conductive liner 116-2. The second conductive liner 116-2 is on and coupled to the second metal layer 118-2 of the MIM stack 118 on the second surface 170-2 of the glass layer 103 and extends at least partially into the vertical structure 112. The second conductive liner 116-2 may include any suitable dimensions and any suitable conductive material, as described above with reference to conductive liner 116 of FIG. 1B.

The configuration of the embodiment shown in FIG. 3B is like that of FIG. 1B, except for differences as described further. The configuration of the VC 190 in FIG. 3B includes a conductive liner 116 that extends conformally along the entire vertical structure 112.

The configuration of the embodiment shown in FIG. 3C is like that of FIG. 3B, except for differences as described further. The configuration of the VC 190 in FIG. 3C includes a first conductive liner 116-1 (e.g., the conductive liner 116, as shown in FIG. 3B) and further includes a second conductive liner 116-2. The second conductive liner 116-2 is on and coupled to the second metal layer 118-2 of the MIM stack 118 on the second surface 170-2 of the glass layer 103 and extends conformally along the entire vertical structure 112.

The configuration of the embodiment shown in FIG. 3D is like that of FIG. 1B, except for differences as described further. The configuration of the VC 190 in FIG. 3D includes a MIM stack 118 that extends only partially into the vertical structure 112, but still entirely covers the conductive liner 116.

FIGS. 4A-41 are side, cross-sectional views of various stages in an example process for manufacturing an example microelectronic assembly according to some embodiments of the present disclosure. Any suitable techniques may be used to manufacture the microelectronic assemblies disclosed herein. For example, FIGS. 4A-41 are side, cross-sectional views of various stages in an example process for manufacturing the VC 190 of the microelectronic assembly 100 of FIG. 1A. Although the operations discussed below with reference to FIGS. 4A-41 are illustrated in a particular order, these operations may be performed in any suitable order. Additionally, although particular assemblies are illustrated in FIGS. 4A-41, the operations discussed below with reference to FIGS. 2A-2J may be used to form any suitable assemblies.

FIG. 4A illustrates an assembly including a glass layer 103 having a first surface 170-1 and a second surface 170-2, and openings 111 at the second surface 170-2 and extending partially through the glass layer 103. The glass layer 103 may have any suitable dimensions, for example, the glass layer 103 may include a full panel glass core having a surface area of approximately 500 millimeters by 500 millimeters (e.g., xy-dimension), or may include a quarter panel glass core having a surface area of approximately 250 millimeters by 250 millimeters. The openings 111 may be formed using any suitable process, including lithography, laser assisted wet etch, laser drilling (e.g., laser ablation using excimer laser), or plasma etching. The openings 111 may have any suitable shape. For example, the openings 111 may have substantially vertical sidewalls to form rectangular-shaped vias or trenches, or may have angled sidewalls to form conical-shaped vias or trenches. The shape of the openings 111 may depend on the process used to form the openings 111 (e.g., a lithographic process for rectangular-shaped and a laser drilling process for conical-shaped).

FIG. 4B illustrates an assembly subsequent to depositing a conductive liner 116 on the second surface 170-2 of the glass layer 103 and at least partially into the opening 111. The conductive liner 116 may be deposited using any suitable technique, for example, PVD or ALD. In some embodiments, the conductive liner 116 extends into the opening 111 to about 20 microns in depth (e.g., z-dimension). In some embodiments, the conductive liner 116 may extend to conformally cover the entire opening 111.

FIG. 4C illustrates an assembly subsequent to depositing a MIM stack 118 on a top surface of the assembly of FIG. 4B. The MIM stack 118 may be deposited using any suitable technique, such as ALD, and may be deposited to conformally blanket the conductive liner 116 and the openings 111.

FIG. 4D illustrates an assembly subsequent to depositing a seed layer 117 on a top surface of the assembly of FIG. 4C. The seed layer 117 may include any suitable conductive material, for example, one or more of copper, titanium, ruthenium, and may be deposited using any suitable technique, such as PVD, ALD, or electroless deposition, to conformally blanket the MIM stack 118. In some embodiments, the seed layer 117 may be deposited on the top surface of the assembly of FIG. 4C and may extend only partially into the openings 111 (e.g., similar to the conductive liner 116, as shown in FIG. 1B). In some embodiments, the seed layer 117 may be omitted.

FIG. 4E illustrates an assembly subsequent to depositing a conductive material 113 in the openings 111 of the assembly of FIG. 4D and forming vertical structures 112 and conductive pads 195. The conductive material 113 may be deposited using any suitable technique, including electroplating.

FIG. 4F illustrates an assembly subsequent to depositing a first mask material 401-1 on a top surface of the assembly of FIG. 4E and removing the seed layer 117, and the second metal layer 118-2, the insulating layer 118-3, and the first metal layer 118-1 of the MIM stack 118 to expose the conductive liner 116. The seed layer 117, the first and second metal layers 118-1, 118-2, and the insulating layer 118-3 may be removed using any suitable technique, such as etching (e.g., wet etching or dry etching).

FIG. 4G illustrates an assembly subsequent to depositing a second mask material 401-2 on a top surface of the assembly of FIG. 4F and depositing a conductive material to form conductive pad 193. The conductive pad 193 may include any suitable conductive material, such as copper, and may be deposited using any suitable technique, including electroplating.

FIG. 4H illustrates an assembly subsequent to stripping the first and second mask materials 401-1, 401-2 and to forming a dielectric material 148 on a top surface of the assembly of FIG. 4G. The dielectric material 148 may be deposited using any suitable technique, including lamination.

FIG. 4I illustrates an assembly subsequent to patterning the dielectric material 148 and depositing a conductive material to form conductive pathways 196 (e.g., vias) through the dielectric material 148 of the assembly of FIG. 4H and coupling the conductive pathways 196 to the conductive pads 193, 195. The conductive pathways 196 coupled to the conductive pad 193 may be connected to a ground source (e.g., VSS) and the conductive pathways 196 coupled to the conductive pads 195 may be connected to a positive voltage supply (e.g., VDD). The dielectric material 148 may be patterned using any suitable technique, such as laser drilling (e.g., carbon dioxide (CO2) laser, a UV laser, or an excimer based laser), a photoimageable dielectric material, or chemical etch or dry etch through a lithography mask. The conductive material may be deposited using any suitable process, such as electroplating, sputtering, or electroless plating. Further manufacturing operations may be performed on the assembly of FIG. 4I to form other microelectronic assemblies 100; for example, forming additional dielectric material 148 and conductive pathways 196 on the first and second surfaces 170-1, 170-2 of the glass layer 103, attaching a circuit board 131 by forming interconnects 150, and attaching dies 114 by forming interconnects 130, similar to FIG. 1A.

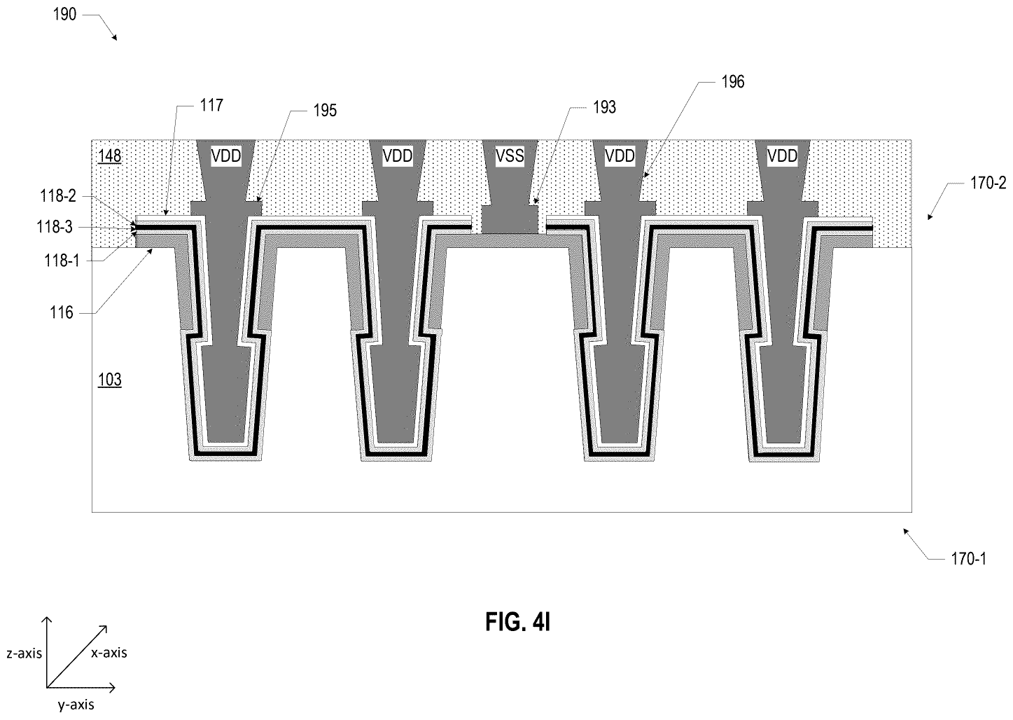

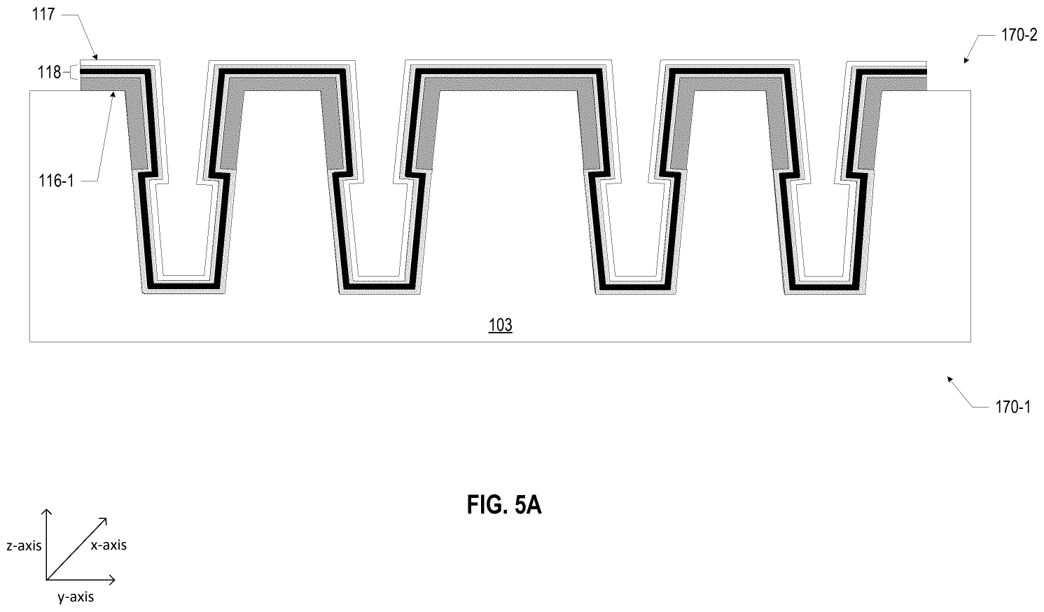

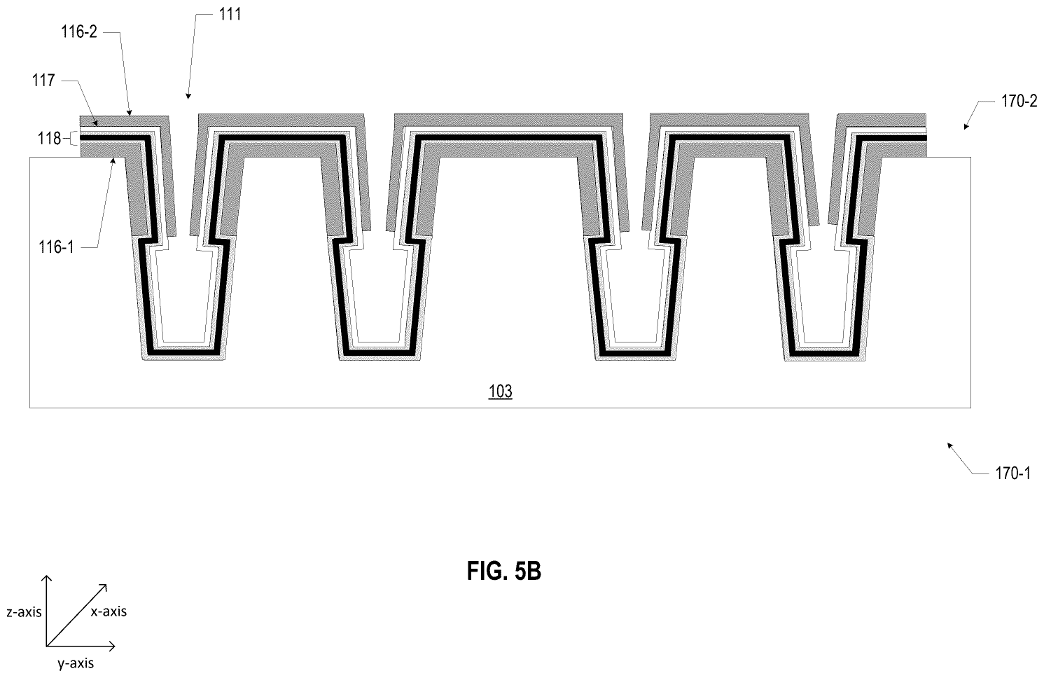

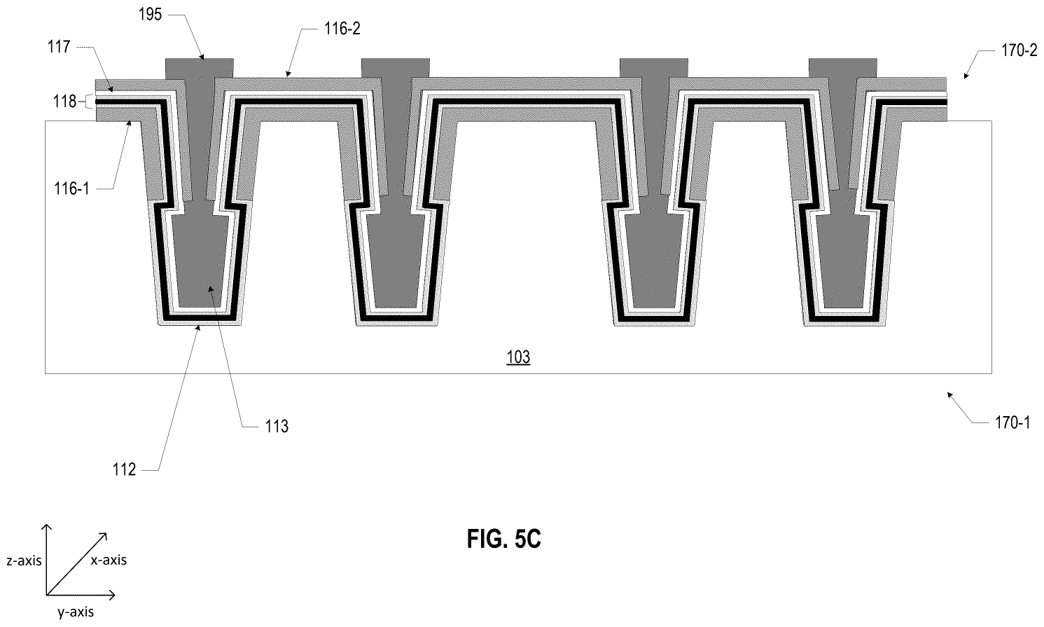

FIGS. 5A-5C are side, cross-sectional views of various stages in an example process for manufacturing another example microelectronic assembly according to some embodiments of the present disclosure. In particular, FIGS. 5A-5C illustrate an example process for forming a microelectronic assembly having a second conductive liner 116-2 (e.g., as shown in FIG. 3A). The assembly of FIG. 5A is like the assembly of FIG. 4D except that the conductive liner is a first conductive liner 116-1. The assembly of FIG. 5A may be formed using any suitable process, including as described above with reference to FIGS. 4A-4D.

FIG. 5B illustrates an assembly subsequent to depositing a second conductive liner 116-2 on the top surface of the seed layer 117 and at least partially in the openings 111 of the assembly of FIG. 5B. The second conductive liner 116-2 may be deposited using any suitable technique, for example, PVD or ALD. In some embodiments, the second conductive liner 116-2 extends into the opening 111 to about 20 microns in depth (e.g., z-dimension). In some embodiments, the second conductive liner 116-2 may extend to conformally cover the entire seed layer 117.

FIG. 5C illustrates an assembly subsequent to depositing a conductive material 113 in the openings 111 of the assembly of FIG. 5B and forming vertical structures 112 and conductive pads 195. The conductive material 113 may be deposited using any suitable technique, including electroplating. The assembly of FIG. 5C may undergo further manufacturing operations, for example, as described above with reference to FIGS. 4E-41.

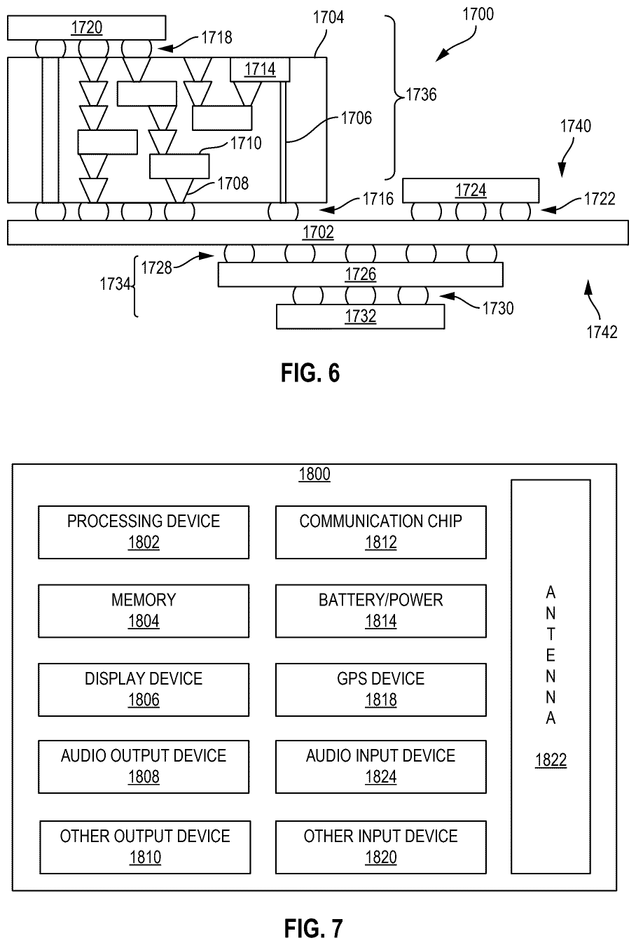

The microelectronic assemblies 100 disclosed herein may be included in any suitable electronic component. FIGS. 6 and 7 illustrate various examples of apparatuses that may include, or be included in, any of the microelectronic assemblies 100 disclosed herein.

FIG. 6 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 6 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 6), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 6, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 6), an IC device (e.g., the IC device 1600 of FIG. 7), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 6, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 6 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 7 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 7 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 7, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

The following paragraphs provide various examples of the embodiments disclosed herein.

Example 1 is an integrated circuit (IC) substrate, including a glass layer having a surface; and a vertical capacitor, the vertical capacitor including a vertical structure extending partially through the glass layer from the surface of the glass layer; a metal-insulator-metal (MIM) stack having a top electrode, an insulator layer, and a bottom electrode, the MIM stack on the surface of the glass layer and extending at least partially into the vertical structure; and a conductive liner layer between the bottom electrode and the glass layer, and electrically coupled to the bottom electrode.

Example 2 may include the subject matter of Example 1, and may further specify that a material of the conductive liner layer includes one or more of copper, silver, gold, aluminum, ruthenium, and tungsten.

Example 3 may include the subject matter of Example 1 or 2, and may further specify that a thickness of the conductive liner layer is between 20 nanometers and 200 nanometers.

Example 4 may include the subject matter of Examples 1-3, and may further specify that a depth of the vertical structure is between 200 microns and 300 microns.

Example 5 may include the subject matter of Examples 1-4, and may further specify that the vertical structure in the glass layer is a blind via.

Example 6 may include the subject matter of Example 5, and may further specify that a diameter of the blind via is between 10 microns and 20 microns.

Example 7 may include the subject matter of Examples 1-6, and may further specify that the vertical structure in the glass layer is a trench.

Example 8 may include the subject matter of Example 7, and may further specify that the trench has a width between 10 microns and 20 microns and a length between 30 microns and 500 microns.

Example 9 may include the subject matter of Examples 1-8, and may further specify that the conductive liner layer is a first conductive liner layer, and the vertical capacitor may further include a second conductive liner layer on the top electrode and electrically coupled to the top electrode.

Example 10 may include the subject matter of Example 9, and may further specify that a material of the second conductive liner layer includes one or more of copper, silver, gold, aluminum, ruthenium, and tungsten.

Example 11 may include the subject matter of Example 9 or 10, and may further specify that a thickness of the second conductive liner layer is between 20 nanometers and 200 nanometers.

Example 12 may include the subject matter of Examples 1-11, and may further specify that the vertical structure in the glass layer is one of a plurality of vertical structures.

Example 13 is an integrated circuit (IC) package, including a package substrate, the package substrate including a glass layer having a surface; and a vertical capacitor, the vertical capacitor including a vertical structure extending partially through the glass layer from the surface of the glass layer; a metal-insulator-metal (MIM) stack having a top electrode, an insulator layer, and a bottom electrode, the MIM stack on the surface of the glass layer and extending at least partially into the vertical structure; and a conductive liner layer between the bottom electrode and the glass layer, and electrically coupled to the bottom electrode; and a die electrically coupled to the package substrate.

Example 14 may include the subject matter of Example 13, and may further specify that a material of the conductive liner layer includes one or more of copper, silver, gold, aluminum, ruthenium, and tungsten.

Example 15 may include the subject matter of Example 13 or 14, and may further specify that a thickness of the conductive liner layer is between 20 nanometers and 200 nanometers.

Example 16 may include the subject matter of Examples 13-15, and may further specify that a depth of the vertical structure is between 200 microns and 300 microns.

Example 17 may include the subject matter of Examples 13-16, and may further specify that the vertical structure in the glass layer is a blind via.

Example 18 may include the subject matter of Examples 13-17, and may further specify that the vertical structure in the glass layer is a trench.

Example 19 is a microelectronic assembly, including a glass layer having a surface; and a vertical capacitor, the vertical capacitor including a plurality of vertical structures extending partially through the glass layer from the surface of the glass layer; a metal-insulator-metal (MIM) stack having a top electrode, an insulator layer, and a bottom electrode, the MIM stack on the surface of the glass layer and extending at least partially into the plurality of vertical structures; and a conductive liner layer between the bottom electrode and the glass layer, and electrically coupled to the bottom electrode.

Example 20 may include the subject matter of Example 19, and may further specify that a material of the conductive liner layer includes one or more of copper, silver, gold, aluminum, ruthenium, and tungsten.

Example 21 may include the subject matter of Example 19 or 20, and may further specify that a thickness of the conductive liner layer is between 20 nanometers and 200 nanometers.

Example 22 may include the subject matter of Examples 19-21, and may further specify that a depth of the plurality of vertical structures is between 200 microns and 300 microns.

Example 23 may include the subject matter of Examples 19-22, and may further specify that the plurality of vertical structures in the glass layer are blind vias.

Example 24 may include the subject matter of Examples 19-23, and may further specify that the plurality of vertical structures in the glass layer are trenches.

Example 25 may include the subject matter of Examples 19-24, and may further include individual first conductive pads electrically coupled to the top electrode of individual ones of the plurality of vertical structures; and a second conductive pad electrically coupled to the conductive liner layer of the plurality of vertical structures.

Example 26 may include the subject matter of Examples 19-25, and may further include a first conductive pad electrically coupled to the top electrode of one or more of the plurality of vertical structures; and a second conductive pad electrically coupled to the conductive liner layer of the plurality of vertical structures.

Example 27 may include the subject matter of Examples 19-26, and may further specify that the vertical capacitor is one of a plurality of vertical capacitors.

1. An integrated circuit (IC) substrate, comprising:
a glass layer having a surface; and
a vertical capacitor, the vertical capacitor including:
a vertical structure extending partially through the glass layer from the surface of the glass layer;
a metal-insulator-metal (MIM) stack having a top electrode, an insulator layer, and a bottom electrode, the MIM stack on the surface of the glass layer and extending at least partially into the vertical structure; and
a conductive liner layer between the bottom electrode and the glass layer, and electrically coupled to the bottom electrode.

2. The IC substrate of claim 1, wherein a material of the conductive liner layer includes one or more of copper, silver, gold, aluminum, ruthenium, and tungsten.

3. The IC substrate of claim 1, wherein a thickness of the conductive liner layer is between 20 nanometers and 200 nanometers.

4. The IC substrate of claim 1, wherein a depth of the vertical structure is between 200 microns and 300 microns.

5. The IC substrate of claim 1, wherein the vertical structure in the glass layer is a blind via.

6. The IC substrate of claim 5, wherein a diameter of the blind via is between 10 microns and 20 microns.

7. The IC substrate of claim 1, wherein the vertical structure in the glass layer is a trench.

8. The IC substrate of claim 7, wherein the trench has a width between 10 microns and 20 microns and a length between 30 microns and 500 microns.

9. The IC substrate of claim 1, wherein the conductive liner layer is a first conductive liner layer, and the vertical capacitor further comprising:
a second conductive liner layer on the top electrode and electrically coupled to the top electrode.

10. The IC substrate of claim 9, wherein a material of the second conductive liner layer includes one or more of copper, silver, gold, aluminum, ruthenium, and tungsten.

11. The IC substrate of claim 9, wherein a thickness of the second conductive liner layer is between 20 nanometers and 200 nanometers.

12. An integrated circuit (IC) package, comprising:
a package substrate, including:
a glass layer having a surface; and
a vertical capacitor, the vertical capacitor including:
a vertical structure extending partially through the glass layer from the surface of the glass layer;
a metal-insulator-metal (MIM) stack having a top electrode, an insulator layer, and a bottom electrode, the MIM stack on the surface of the glass layer and extending at least partially into the vertical structure; and
a conductive liner layer between the bottom electrode and the glass layer, and electrically coupled to the bottom electrode; and
a die electrically coupled to the package substrate.

13. The IC package of claim 12, wherein a material of the conductive liner layer includes one or more of copper, silver, gold, aluminum, ruthenium, and tungsten.

14. The IC package of claim 12, wherein a thickness of the conductive liner layer is between 20 nanometers and 200 nanometers.

15. The IC package of claim 12, wherein a depth of the vertical structure is between 200 microns and 300 microns.

16. A microelectronic assembly, comprising:
a glass layer having a surface; and
a vertical capacitor, the vertical capacitor including:
a plurality of vertical structures extending partially through the glass layer from the surface of the glass layer;
a metal-insulator-metal (MIM) stack having a top electrode, an insulator layer, and a bottom electrode, the MIM stack on the surface of the glass layer and extending at least partially into the plurality of vertical structures; and
a conductive liner layer between the bottom electrode and the glass layer, and electrically coupled to the bottom electrode.

17. The microelectronic assembly of claim 16, wherein a material of the conductive liner layer includes one or more of copper, silver, gold, aluminum, ruthenium, and tungsten.

18. The microelectronic assembly of claim 16, further comprising:
individual first conductive pads electrically coupled to the top electrode of individual ones of the plurality of vertical structures; and
a second conductive pad electrically coupled to the conductive liner layer of the plurality of vertical structures.

19. The microelectronic assembly of claim 16, further comprising:
a first conductive pad electrically coupled to the top electrode of one or more of the plurality of vertical structures; and
a second conductive pad electrically coupled to the conductive liner layer of the plurality of vertical structures.

20. The microelectronic assembly of claim 16, wherein the vertical capacitor is one of a plurality of vertical capacitors.
